(19) United States
(12) Patent Application Publication
(10) Pub. No.: US 2003/0219996 A1
(43) Pub. Date: Nov. 27, 2003

(54) Method of forming a sealing layer on a copper pattern

(76) Inventor: Shyh-Dar Lee, Hsinchu Hsien (TW)

Correspondence Address: Tim Tingkang Xia, Esq., NEEDLE & ROSENBERG, P.C., The Candler Building, Suite 1200, 127 Peachtree Street, N.E., Atlanta, GA, 30303-1811, US

(21) Appl. No.: 10/155,718

(22) Filed: May 24, 2002

(51) Int. Cl. H01L 21/31

(52) U.S. Cl. 438/785

(57) ABSTRACT

A method of forming a sealing layer on a copper pattern. First, a semiconductor substrate having a copper pattern is provided. Then, a tantalum layer is deposited on the upper surface of the copper pattern by atomic layer chemical vapor deposition (ALCVD). Nitrogen gas is then introduced to react with the upmost atomic layer of the tantalum layer so as to form a sealing layer comprising tantalum nitride.

### BACKGROUND OF THE INVENTION

1. Field of the Invention

The present invention relates to the manufacture of semiconductor devices, more particularly to a method of forming a sealing layer on a copper pattern.

2. Description of the Related Art

Semiconductor manufacturers must continually improve the power and performance of semiconductor devices while keeping device size to a minimum. In an effort to maintain a small device size, most semiconductor manufacturers reduce individual components of the device to minimal dimensions. Furthermore, manufacturers are using methods such as vertical integration of the components, to reduce the device area consumed by the components. But by packing the components in a higher and higher density, the need for higher performance interconnects arises. As the cross sectional areas of the interconnects shrinks, line resistance and current density capacity become limiting factors in total chip performance. For example, aluminum, which has commonly been used for interconnects, has problems associated with electromigration and lowered heat dissipation. Copper, which has a lower resistivity and a greater electromigration lifetime, eliminates many of the existing problems associated with using aluminum. However, there are difficulties with fabricating copper interconnects using conventional etching techniques since copper material does not lend itself well to conventional plasma etching.

A recent approach to solving the problem of interconnecting the various conductive layers involves etch and mask sequences generally known in the art as damascene techniques. The damascene technique involves forming a plurality of trenches in a layer of insulator and subsequently filling them with metal, by way of example, copper, which is then polished down to the surface of the insulator to form the desired metal pattern. In a process generally known as dual damascening, both the metal trenches as described above and the via interconnects electrically connecting the aforementioned metal pattern and various other conductive layers are typically filled substantially simultaneously.

By way of example, FIG. 1 is a cross-section showing the copper damascene structure with a sealing layer fabricated by the prior art.

As shown in FIG. 1, a semiconductor substrate 10 having a dielectric layer 12 is provided. Then, damascene structures are created in the dielectric layer 12. A barrier layer 14 is conformally deposited in the damascene structure and on the dielectric layer 12 followed by formation of a copper layer 15 using electroplating and chemical mechanical polishing (CMP). A sealing layer 16 consisting of silicon nitride or silicon oxynitride is covered on the semiconductor substrate 10 by plasma enhanced chemical vapor deposition (PECVD). The sealing layer 16 is used to prevent copper ion migration to the dielectric layer 18. Also, the sealing layer 16 can serve as the etching stop layer. Copper damascene structures 20 are then formed in the dielectric layer 18.

However, a poor adhesion problem exists between the conventional sealing layer, of silicon nitride or silicon oxynitride, and the underlying copper pattern because there is no compound formation between copper and silicon nitride or silicon oxynitride. Furthermore, because silicon nitride or silicon oxynitride has a high dielectric constant, the sealing layer increases the resistance capacitance (RC) between interconnects thereby having a negative effect on device performance.

### SUMMARY OF THE INVENTION

In view of the above disadvantages, an object of the invention is to provide a method of forming a sealing layer on a copper pattern capable of reducing the RC of the Cu pattern thus improving device performance.

A further object of the invention is to provide a method of forming a sealing layer on a copper pattern. The sealing layer can provide good adhesion to the underlying copper pattern.

In accordance with one aspect of the invention, there is provided a method of forming a sealing layer on a copper pattern. First, a semiconductor substrate having a copper pattern is provided. Then, a tantalum layer is deposited on the upper surface of the copper pattern by atomic layer chemical vapor deposition (ALCVD). Nitrogen gas is then introduced to react with the upmost atomic layer of the tantalum layer so as to form a sealing layer comprising tantalum nitride.

In accordance with another aspect of the invention, there is provided a method of forming a sealing layer on a copper pattern.

In accordance with a further aspect of the invention, there is provided a method of forming a sealing layer on a copper pattern. The method further comprises the steps of: depositing a dielectric layer on the semiconductor substrate; selectively etching the dielectric layer to form a damascene structure; electroplating a copper layer into the damascene structure; and planarizing the copper layer to leave a copper pattern and expose the dielectric layer.

In accordance with yet another aspect of the invention, there is provided a method of forming a sealing layer on a copper pattern. The tantalum layer is deposited by delivering a tantalum organic precursor to the deposition reactor. The deposition reactor can be a metal-organic chemical vapor disposition chamber. Also, the flow rate of the tantalum organic precursor is from 5 to 15 sccm, and the tantalum layer is deposited while helium or argon is used as the carrier gas at a temperature of about 250° C. and about 450° C. so that the tantalum layer comprises 2 to 15 tantalum atomic layers.

In accordance with a still further aspect of the invention, there is provided a method of forming a sealing layer on a copper pattern. The nitrogen gas is introduced at a temperature of about 400° C. to 450° C. for about 20-40 seconds. Furthermore, the tantalum layer can be a self-aligned deposited layer.

In accordance with a still further aspect of the invention, there is provided a method of forming a sealing layer on a copper pattern. The method further comprises the steps of: depositing a dielectric layer on the semiconductor substrate to overlay the sealing layer; creating a dual damascene structure in the dielectric layer by selectively etching; and electroplating a copper layer into the dual damascene structure.

In accordance with yet another aspect of the invention, there is provided a method of forming a sealing layer on a copper pattern. First, a semiconductor substrate having a copper pattern is provided. Next, a self-aligned metal layer, such as titanium, tantalum, or tungsten is deposited on the upper surface of the copper pattern by atomic layer chemical vapor deposition (ALCVD). Then, nitrogen gas is introduced to react with the upmost atomic layer of the metal layer so as to form a sealing layer comprising metallic nitride.

### BRIEF DESCRIPTION OF THE DRAWINGS

The preferred embodiment of the invention is hereinafter described with reference to the accompanying drawings in which:

FIG. 1 is a cross-section showing the copper damascene structure with a sealing layer fabricated by the prior art.

FIGS. 2A to 2H, are cross-sections showing the manufacturing steps of fabricating a copper damascene structure in accordance with the embodiment of the invention.

FIG. 3 is a part of the atomic stacked structure of the sealing layer formed by the embodiment of the invention.

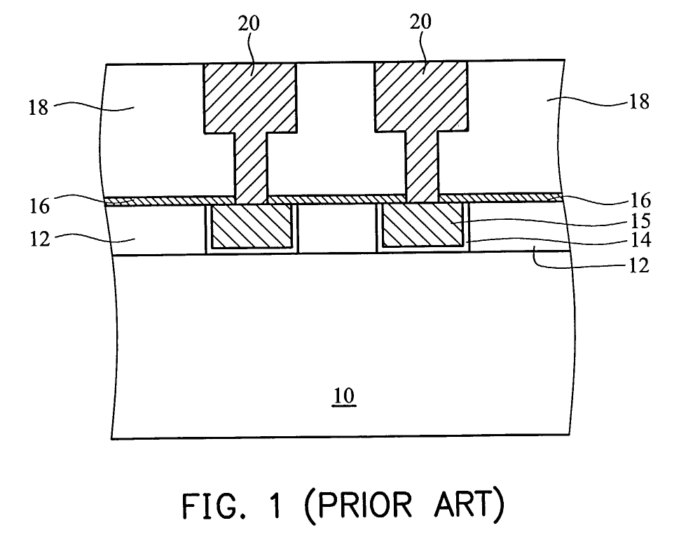

### DETAILED DESCRIPTION OF THE INVENTION

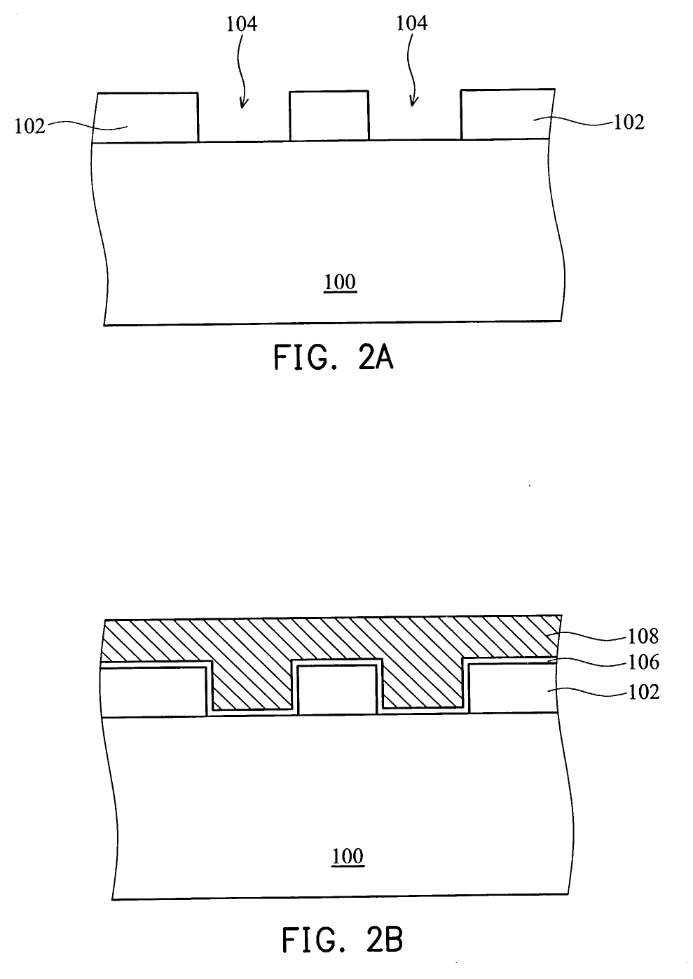

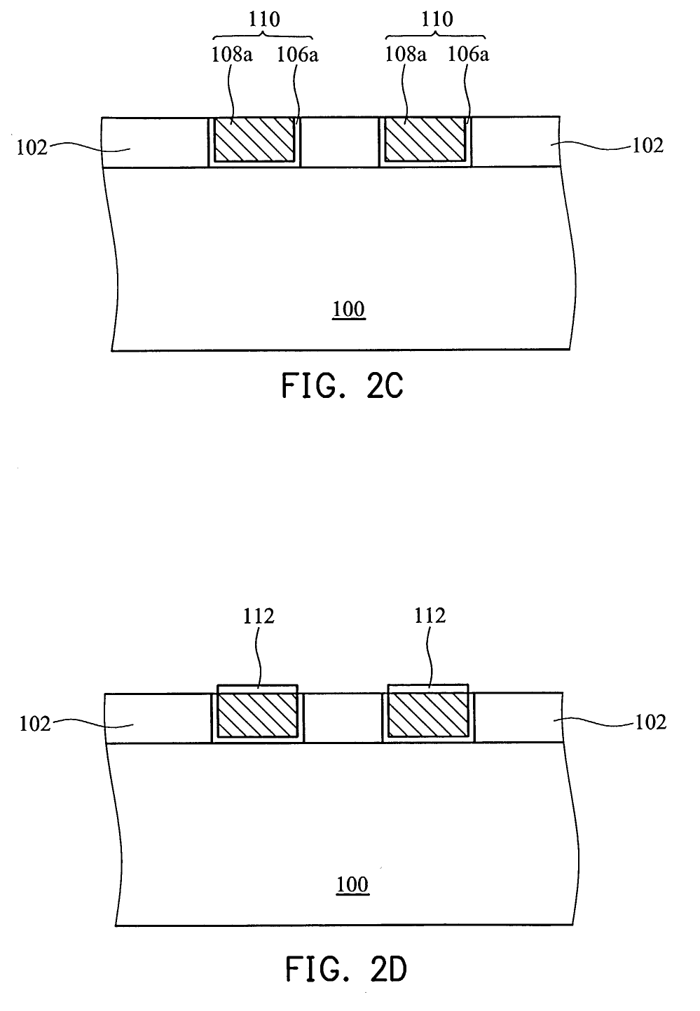

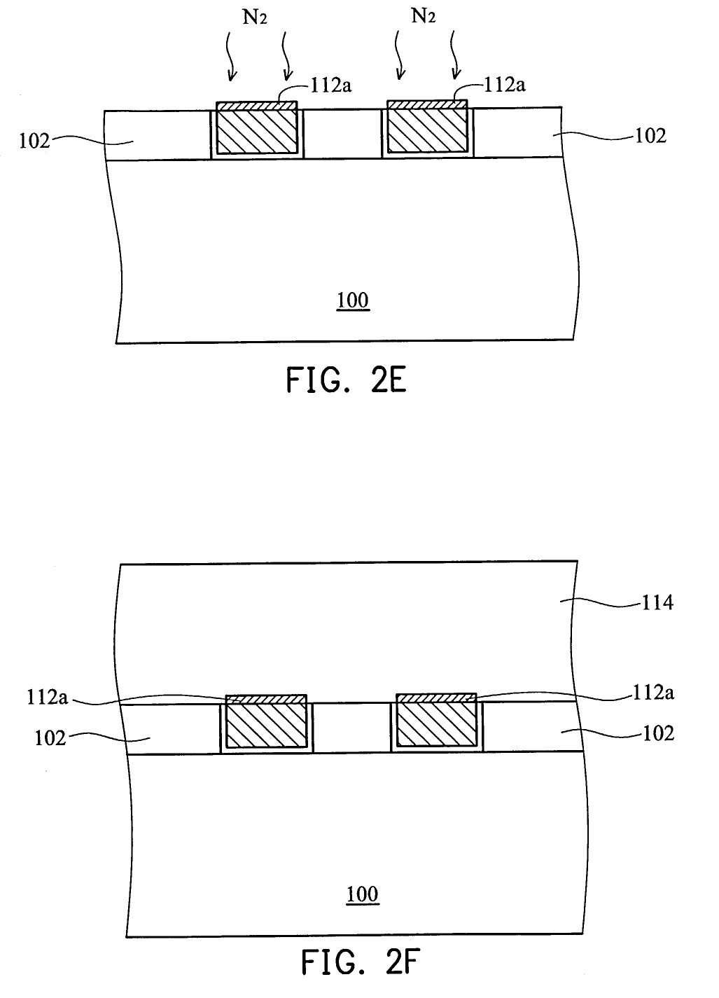

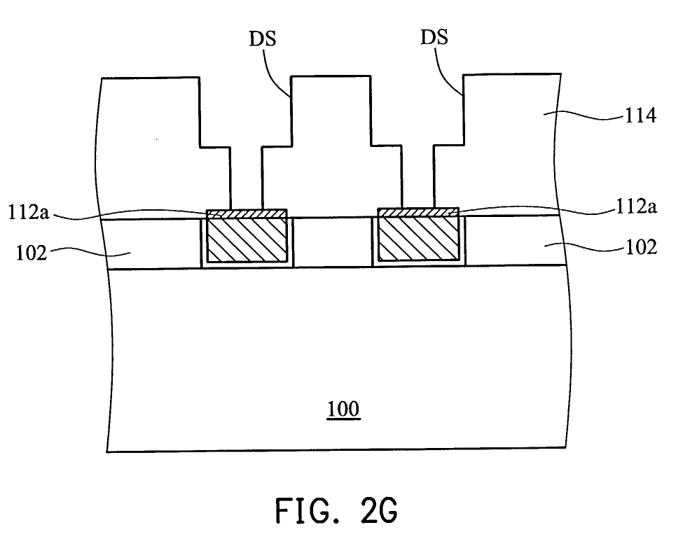

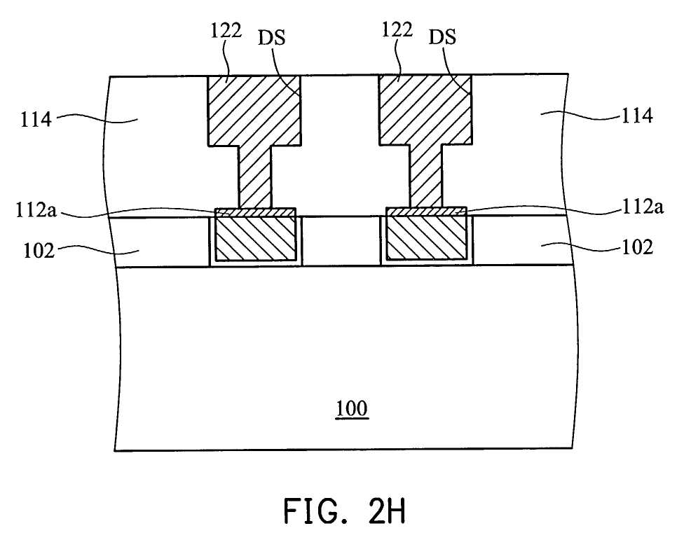

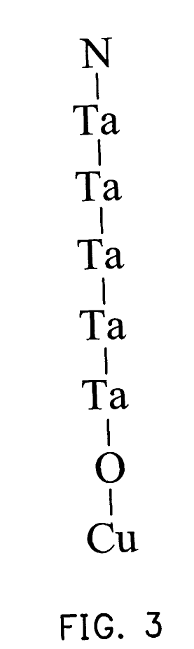

FIGS. 2A to 2H, are cross-sections showing the manufacturing steps of fabricating a copper damascene structure in accordance with the embodiment of the invention. Also, FIG. 3 is a part of the atomic stacked structure of the sealing layer formed by the embodiment of the invention.

As shown in FIG. 2A, a semiconductor substrate 100 of single-crystalline having a dielectric layer 102 is provided. The dielectric layer 102 is preferably silicon oxide or low k organic material. Then, damascene structures 104 are created in the dielectric layer 102 by conventional photolithography and etching. Next, as shown in FIG. 2B, a barrier layer 106 consisting of titanium nitride or tantalum nitride is conformally deposited on the damascene structure 104 and the dielectric layer 102 followed by formation of a copper layer 108 using electroplating.

Next, referring to FIG. 2C, the copper layer 108 and the barrier layer 106 are planarized by chemical mechanical polishing thus leaving a copper pattern 110 consisting of barrier layer 106a and copper 108a filled within the damascene structure 104. A copper oxide (for clarity, not shown) is spontaneously grown on the upper surface of the copper pattern 110 so as to provide a reactive site for deposition of a self-aligned tantalum.

Referring now to FIG. 2D, a tantalum layer 112 is selectively deposited on the upper surface of the copper pattern 110 by atomic layer chemical vapor deposition (ALCVD). The tantalum layer 112 is deposited by delivering a tantalum organic precursor to a metal-organic chemical vapor deposition (MOCVD) reactor while helium or argon gas is used as the carrier gas. Furthermore, the tantalum layer 112 is deposited at a temperature of about 250° C. and about 450° C. so that the tantalum layer 112 comprises 5 tantalum atomic layers as shown in FIG. 3.

Next, as shown in FIG. 2E and FIG. 3, the semiconductor substrate 100 is transferred to a chamber for nitrogen annealing. Nitrogen gas is introduced into the chamber at a temperature of about 400° C. to 450° C. for 30 seconds so that nitrogen is reacted with the upmost atomic layer of the tantalum layer 112 so as to form a sealing layer 112a comprising tantalum nitride capable of preventing copper migration.

Referring now to FIG. 2F, a dielectric layer 114, of silicon oxide or low k organic material, is deposited on the semiconductor substrate 100 and the sealing layer 112a. Next, as shown in FIG. 2G, dual damascene structures DS are created by conventional via-first or conventional trench-first technique.

Afterward, as shown in FIG. 2H, a copper layer is electroplated on the semiconductor substrate 100 to fill the dual damascene structure DS. Then, the copper layer is planarized by chemical mechanical polishing to leave copper damascene structures 122 formed in the dual damascene structure DS.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. A method of forming a sealing layer on a copper pattern, comprising the steps of:
providing a semiconductor substrate having a copper pattern;
depositing a tantalum layer on the upper surface of the copper pattern by atomic layer chemical vapor deposition (ALCVD); and
introducing nitrogen gas to react with the upmost atomic layer of the tantalum layer so as to form a sealing layer comprising tantalum nitride.

2. A method of forming a sealing layer on a copper pattern as claimed in claim 1, wherein formation of the copper pattern further comprises the steps of:
depositing a dielectric layer on the semiconductor substrate;
selectively etching the dielectric layer to form a damascene structure;
electroplating a copper layer into the damascene structure; and
planarizing the copper layer to leave a copper pattern and expose the dielectric layer.

3. A method of forming a sealing layer on a copper pattern as claimed in claim 1, wherein the tantalum layer is deposited by delivering a tantalum organic precursor to the deposition reactor.

4. A method of forming a sealing layer on a copper pattern as claimed in claim 3, wherein the flow rate of the tantalum organic precursor is from 5 to 15 sccm.

5. A method of forming a sealing layer on a copper pattern as claimed in claim 4, wherein the tantalum layer is deposited while helium or argon is used as the carrier gas.

6. A method of forming a sealing layer on a copper pattern as claimed in claim 3, wherein the tantalum layer is deposited at a temperature of about 250° C. and about 450° C.

7. A method of forming a sealing layer on a copper pattern as claimed in claim 1, wherein the tantalum layer comprises 2 to 15 tantalum atomic layers.

8. A method of forming a sealing layer on a copper pattern as claimed in claim 1, wherein the nitrogen gas is introduced at a temperature of about 400° C. to 450° C. for about 20-40 seconds.

9. A method of forming a sealing layer on a copper pattern as claimed in claim 1, wherein the tantalum layer is a self-aligned deposited layer.

10. A method of forming a sealing layer on a copper pattern as claimed in claim 1, further comprising the steps of:
depositing a dielectric layer on the semiconductor substrate to overlay the sealing layer;
creating a dual damascene structure in the dielectric layer by selectively etching; and
electroplating a copper layer into the dual damascene structure.

11. A method of forming a self-aligned sealing layer on a copper pattern, comprising the steps of:
providing a semiconductor substrate having a copper pattern;
depositing a self-aligned metal layer on the upper surface of the copper pattern by atomic layer chemical vapor deposition (ALCVD); and
introducing nitrogen gas to react with the upmost atomic layer of the metal layer so as to form a sealing layer comprising metallic nitride.

12. A method of forming a self-aligned sealing layer on a copper pattern as claimed in claim 11, wherein the self-aligned metal layer is tantalum, titanium, or tungsten.

13. A method of forming a sealing layer on a copper pattern as claimed in claim 11, wherein formation of the copper pattern further comprises the steps of:
depositing a dielectric layer on the semiconductor substrate;
selectively etching the dielectric layer to form a damascene structure;
electroplating a copper layer into the damascene structure; and
planarizing the copper layer to leave a copper pattern and expose the dielectric layer.

14. A method of forming a sealing layer on a copper pattern as claimed in claim 11, wherein the metal layer is deposited by delivering a metallic organic precursor to the deposition reactor.

15. A method of forming a sealing layer on a copper pattern as claimed in claim 11, wherein the metal layer is deposited while helium or argon is used as the carrier gas.

16. A method of forming a sealing layer on a copper pattern as claimed in claim 11, wherein the metal layer comprises 2 to 15 metal atomic layers.

17. A method of forming a sealing layer on a copper pattern as claimed in claim 11, further comprising the steps of:
depositing a dielectric layer on the semiconductor substrate to overlay the sealing layer;
creating a dual damascene structure in the dielectric layer by selectively etching; and
electroplating a copper layer into the dual damascene structure.
